(19) United States
(12) Patent Application Publication
(10) Pub. No.: US 2013/0295767 A1
(43) Pub. Date: Nov. 7, 2013

(54) INCREASED TRANSISTOR PERFORMANCE BY IMPLEMENTING AN ADDITIONAL CLEANING PROCESS IN A STRESS LINER APPROACH

(71) Applicants: Thilo Scheiper, Dortmund (DE); Peter Baars, Dresden (DE)

(72) Inventors: Thilo Scheiper, Dortmund (DE); Peter Baars, Dresden (DE)

(73) Assignee: GLOBALFOUNDRIES INC., Grand Cayman (KY)

(21) Appl. No.: 13/462,246

(22) Filed: May 2, 2012

(51) Int. Cl. H01L 21/28; H01L 21/3065

(52) U.S. Cl. 438/682; 438/703; 257/E21.158; 257/E21.218

(57) ABSTRACT

When forming sophisticated transistors on the basis of a highly stressed dielectric material formed above a transistor, the stress transfer efficiency may be increased by reducing the size of the spacer structure of the gate electrode structure prior to depositing the highly stressed material. Prior to the deposition of the highly stressed material, an additional cleaning process may be implemented in order to reduce the presence of any metal contaminants, in particular in the vicinity of the gate electrode structure, which would otherwise result in an increased fringing capacitance.

### BACKGROUND OF THE INVENTION

1. Field of the Invention

Generally, the present disclosure relates to the field of integrated circuits, and, more particularly, to the manufacture of field effect transistors having a strained channel region caused by a stressed dielectric material formed above the transistor.

2. Description of the Related Art

Integrated circuits typically comprise a large number of circuit elements on a given chip area according to a specified circuit layout, wherein, in complex circuits, the field effect transistor represents the dominant device component. Generally, a plurality of process technologies are currently practiced, wherein, for complex circuitry based on field effect transistors, such as microprocessors, storage chips and the like, MOS technology is one of the most promising approaches due to the superior characteristics in view of operating speed and/or power consumption and/or cost efficiency. During the fabrication of complex integrated circuits using MOS technology, millions of transistors, in CMOS technology, complementary transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the majority charge carriers and, for a given extension of the channel region in the transistor width direction, the distance between the source and drain regions, which is also referred to as channel length. Hence, the conductivity of the channel region represents an important factor that substantially affects performance of the MOS transistors. Thus, the reduction of the channel length may be a dominant design criteria for accomplishing an increase in the operating speed of integrated circuits.

The shrinkage of the transistor dimensions, however, involves a plurality of issues associated therewith that have to be addressed so as to not unduly offset the advantages obtained by steadily decreasing the channel length of MOS transistors. One problem in this respect is the reduction of the thickness of the gate dielectric layer in order to maintain the desired channel controllability on the basis of increased capacitive coupling. With the thickness of oxide-based gate dielectrics approaching 1.5 nm and less, the further scaling of the channel length may be difficult due to an unacceptable increase of leakage currents through the gate dielectric. For this reason, it has been proposed to enhance device performance of the transistor elements not only by reducing the transistor dimensions, but also by increasing the charge carrier mobility in the channel region for a given channel length. One efficient approach in this respect is the modification of the lattice structure in the channel region, for instance by creating tensile or compressive strain therein, which results in a modified mobility for electrons and holes, respectively. For example, creating tensile strain in the channel region of a silicon layer having a standard crystallographic configuration may increase the mobility of electrons, which, in turn, may directly translate into a corresponding increase of the conductivity and hence overall performance of N-type transistors. On the other hand, compressive strain in the channel region may increase the mobility of holes, thereby providing the potential for enhancing performance of P-type transistors. Consequently, it has been proposed to introduce, for instance, a silicon/germanium layer or a silicon/carbon layer in or near the channel region so as to create tensile or compressive stress. Although the transistor performance may be considerably enhanced by the introduction of strain-creating layers in or below the channel region, significant efforts and, hence, additional process steps have to be made in conventional and well-approved CMOS techniques. For instance, additional epitaxial growth techniques have to be developed and implemented into the process flow so as to form the germanium or carbon-containing stress layers at appropriate locations in or below the channel region. Hence, process complexity is significantly increased, thereby also increasing production costs and the potential for a reduction in production yield.

Therefore, a technique is frequently used that enables the creation of desired stress conditions within the channel region of different transistor elements by modifying the stress characteristics of a material that is positioned in close proximity to the transistor structure in order to allow an efficient stress transfer to the channel region. For example, the spacer typically provided at sidewalls of the gate electrodes and the interlayer dielectric material or a portion thereof, such as a contact etch stop layer, that is formed above the basic transistor structure are promising candidates for creating external stress which may then be transferred into the transistor. In particular, the contact etch stop layer used for controlling an etch process designed to form contact openings in the interlayer dielectric material to the gate, drain and source regions may thus be efficiently employed for generating a desired type of strain in the channel regions. The effective control of mechanical stress transferred into the channel region, i.e., an effective stress engineering, may be accomplished for different types of transistors by individually adjusting the internal stress level in the contact etch stop layers located above the respective transistor elements so as to position a contact etch stop layer having an internal compressive stress above a P-channel transistor while positioning a contact etch stop layer having an internal tensile strain above an N-channel transistor, thereby creating compressive and tensile strain, respectively, in the channel regions.

Typically, the contact etch stop layer is formed by plasma enhanced chemical vapor deposition (PECVD) processes above the transistor, i.e., above the gate structure and the drain and source regions, wherein, for instance, silicon nitride may be used due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher compressive stress, while stress levels of 1.5 GPa and higher may be obtained for tensile-stressed silicon nitride materials, wherein the type and the magnitude of the intrinsic stress may be efficiently adjusted by selecting appropriate deposition parameters. For example, ion bombardment, deposition pressure, substrate temperature, the type of gas components and the like represent suitable parameters that may be tuned for obtaining the desired intrinsic stress. As explained before, the contact etch stop layer is positioned close to the transistor so that the intrinsic stress may be efficiently transferred into the channel region, thereby significantly improving the performance thereof. Moreover, for advanced applications, the strain-inducing contact etch stop layer may be efficiently combined with other strain-inducing mechanisms, such as strained or relaxed semiconductor materials that are incorporated at appropriate transistor areas in order to also create a desired strain in the channel region.

Upon the introduction of gate lengths of 50 nm and less, however, it turns out that the above-described strain-inducing mechanism based on different dielectric materials formed above respective transistors may be less efficient since reduced overall transistor dimensions may require a corresponding adaptation of the thickness of the highly stressed dielectric materials, thereby reducing the effective strain induced in the corresponding channel regions. Since the internal stress level of the dielectric materials may not be efficiently increased on the basis of presently available deposition recipes, the effective lateral offset of the strain-inducing dielectric material has to be reduced, wherein typically the size of a sidewall spacer structure is reduced, as will be described in more detail with reference to FIGS. 1a-1c.

FIG. 1a schematically illustrates a cross-sectional view of a semiconductor device 100 in a moderately advanced manufacturing stage. As shown, a transistor 150b and a transistor 150a are formed in and above a semiconductor layer 102, which in turn is provided on or above an appropriate substrate 101, such as a silicon substrate and the like. The semiconductor layer 102 is comprised of any appropriate semiconductor material, such as silicon, silicon/germanium and the like, as is required for forming therein and thereon the transistors 150a, 150b. The semiconductor layer 102 may thus comprise a plurality of active regions 102a, 102b which are typically laterally delineated by respective isolation structures (not shown), such as shallow trench isolations and the like. It should be appreciated that a buried insulating material (not shown) may be provided below the semiconductor layer 102 if an SOI (silicon-on-insulator) architecture is contemplated. In the example shown, the transistors 150a, 150b may be of different conductivity type, wherein, for example, the transistor 150b represents an N-channel transistor, while the transistor 150a is to represent a P-channel transistor. In this manufacturing stage, the transistors 150a, 150b comprise drain and source regions 151 having any appropriate lateral and vertical dopant profile. Furthermore, metal silicide regions 152 are formed in the drain and source regions so as to provide superior conductivity. Furthermore, the transistor 150a comprises a gate electrode structure 160a, which in turn may include a gate dielectric layer 161 that separates a gate electrode material 163, such as a silicon material, possibly in combination with other metal-containing electrode materials, such as titanium nitride and the like, followed by a metal silicide region 162. Moreover, a sidewall spacer structure 164 is provided on sidewalls of the materials 161, 163 and 162, wherein the structure 164 may typically include one or more individual spacer elements, such as elements 164b and 164d, possibly in combination with intermediate etch stop liner materials 164a, 164c. For example, frequently, silicon nitride is used as a material for the spacer elements 164b, 164d, while silicon dioxide is frequently used as an etch stop material of the liners 164a, 164c.

It should be appreciated that a gate electrode structure 160b of the transistor 150b may have basically the same configuration as the structure 160a. In sophisticated applications, the gate electrode structures 160a, 160b, however, may differ in their configuration, for instance with respect to certain work function metal species and the like, when a high-k dielectric material is incorporated in the gate dielectric layers 161 in combination with appropriate metal-containing electrode materials, which may be provided within the material 163. Using a high-k dielectric material, which is to be understood as a dielectric material having a dielectric constant of 10.0 or higher, in the gate dielectric layer 161 may impart increased leakage current blocking capabilities to the gate dielectric layers 161, while nevertheless allowing an increased capacitive coupling to be achieved compared to extremely thin silicon dioxide-based gate dielectric materials. In any such sophisticated gate electrode structures, the spacer structure 164 may additionally comprise an appropriate liner material (not shown) which may be formed on sidewalls of the sensitive materials 161 and 163 prior to forming the spacer structure 164. That is, upon using highly sensitive materials, such as high-k dielectric materials and the like, in an early manufacturing stage, any undue exposure to critical process atmospheres, such as oxygen and the like, has to be avoided in order to not unduly shift the overall characteristics of these materials.

The semiconductor device 100 as illustrated in FIG. 1a may be formed on the basis of the following processes. The active regions 102a, 102b are typically formed by incorporating appropriate isolation structures into the layer 102, which in turn is accomplished by applying well-established lithography, etch, deposition and anneal techniques so as to form isolation trenches to provide appropriately dimensioned active regions in the layer 102. Prior to or after forming the isolation structures, dopant species may be introduced into the active regions 102a, 102b in order to define the basic transistor characteristics. Thereafter, the gate electrode structures 160a, 160b are formed by depositing or otherwise forming appropriate materials for the gate dielectric layer 161, wherein the deposition of one or more metal-containing electrode materials may follow if a sophisticated high-k metal gate electrode structure is to be provided in this early manufacturing stage. To this end, well-established yet highly complex deposition, patterning and diffusion processes may have to be applied. Thereafter, the one or more materials 163 may be deposited in combination with any additional sacrificial materials as are required for performing a sophisticated lithography process and a subsequent patterning sequence in order to define the required gate length, which is to be understood as the horizontal dimension of the electrode material 163 in FIG. 1a. Thereafter, a liner material may be formed, for instance, on the basis of silicon nitride, if sensitive gate materials have been used, as discussed above. Next, a portion of the spacer structure 164, such as the liner 164a and the spacer element 164b, may be formed by applying well-established deposition and etch recipes. For example, plasma assisted etch chemistries for etching silicon nitride selectively with respect to silicon dioxide are well established in the art and may be efficiently used. Thereafter, drain and source dopant species, possibly in combination with further well dopant species, may be incorporated, followed by further deposition and etch processes in order to complete the spacer structure 164, for instance by forming the liner 164c and the spacer element 164d. Next, further drain and source dopant species may be incorporated as required for obtaining a specified dopant concentration and a corresponding vertical dopant profile, while the spacer structures 164 may be used as efficient implantation masks. After any high temperature processes for activating previously implanted dopant species and for reducing implantation-induced lattice damage in the active regions 102a, 102b, the metallization system regions 152, 162 are formed, for instance, by using well-established silicidation regimes. For example, frequently, a nickel silicide is formed in sophisticated applications due to the superior conductivity of nickel silicide compared to other well-established silicide materials. It should be appreciated, however, that other materials, such as platinum and the like, may also be incorporated in the regions 152, 162, depending on the overall device requirements.

In this manufacturing stage, the spacer structures 164 may be efficiently used as a mask for the implantation processes and also for the silicidation process, thereby substantially determining the lateral offset of the regions 152 with respect to channel regions 153 of the transistors 150a, 150b. Hence, when the spacer structures 164 are typically formed commonly for the transistors 150a, 150b, pronounced stress characteristics may not be implemented for these structures, since stress characteristics that would positively influence one transistor would significantly deteriorate performance of the other transistor. On the other hand, the spacer structure 164 prevents an efficient deposition of a highly stressed dielectric material in close proximity to the channel regions 153, thereby reducing the overall efficiency of a corresponding strain-inducing mechanism. For this reason, in advanced approaches, a plasma assisted etch process 103 is applied so as to reduce the overall size of the spacer structure 164. To this end, any well-established plasma assisted etch recipe may be applied so as to remove silicon nitride material selectively with respect to silicon dioxide and also selectively with respect to the metal silicide regions 152, 162. To this end, well-established plasma-based silicon nitride etch recipes may be applied. It should be appreciated that using a plasma-based etch recipe may ensure superior controllability of the material removal and thus of the final size of the resulting spacer structure, while also a removal of silicon nitride liner materials at critical device areas, i.e., in the vicinity of the gate dielectric material 161, if comprising a high-k dielectric material, may be substantially suppressed.

FIG. 1b schematically illustrates the semiconductor device 100 in a further advanced manufacturing stage. As illustrated, a spacer structure of reduced size is formed on the gate electrode structures 160a, 160b, wherein these spacer structures of reduced size are indicated by 164r. As shown, a size reduction in height and width may have been accomplished during the preceding plasma assisted etch process, wherein the degree of material removal may be selected in accordance with overall process and device requirements. It should be appreciated that the outer spacer element 164d (FIG. 1a) may be completely removed, if considered appropriate, while in the example shown portions of the spacer element may still be retained.

Furthermore, a strain-inducing dielectric layer 122b is formed above the transistors 150a, 150b, typically in combination with an etch stop liner 121, such as a silicon dioxide material and the like. As discussed above, the strain-inducing layer 122b may typically be provided in the form of a silicon nitride material having a high internal stress level so as to induce a desired type of strain in one of the transistors 150a, 150b. For example, the layer 122b is provided so as to have a high tensile stress level, which may thus result in superior performance of the N-channel transistor 150b. The layers 121, 122b are deposited on the basis of well-established deposition recipes while tuning the process parameters so as to obtain the desired high stress level and to provide a thickness of the layer 122b that is compatible with the further processing of the device 100. It should be appreciated that, due to the reduced size of the spacer structure 164r, generally, superior transfer of stress from the material 122b into the channel regions of the transistors 150a, 150b may be achieved.

FIG. 1c schematically illustrates the device 100 according to a well-established dual stress liner approach in which a portion of the previously formed layer 122b is selectively removed above the transistor 150a, possibly in combination with the etch stop liner 121, which is typically accomplished by masking the transistor 150b and performing a corresponding etch sequence for etching through the layer 122b while using the layer 121 as an etch stop layer. Thereafter, residues of the layer 121 are typically removed on the basis of a corresponding etch step, which may include a cleaning process so as to prepare the device 100 for the deposition of a further strain-inducing material. For example, as shown, a further etch stop layer 123 in combination with a further strain-inducing layer 122a is formed above the transistors 150a, 150b, wherein the internal stress level of the layer 122a is selected so as to provide a desired type of strain in the channel region 153, wherein also the reduced size of the spacer structure 164r ensures superior stress transfer efficiency. The layer 123, if provided, and the layer 122a are formed on the basis of well-established deposition recipes. Thereafter, typically, the portion of the layer 122a is removed from above the transistor 150b, wherein the layer 123, if provided, may be used as an etch stop liner, while in other cases a time-controlled etch process is applied.

Thus, the above-described process sequence allows different strain to be induced in the transistors 150a, 150b at a moderately high efficiency due to the reduced size of the spacer structure, thereby achieving superior signal processing performance, for instance in terms of switching speed and the like, for transistors of different conductivity type. Upon quantitatively determining performance of the transistors of the device 100, however, it turns out that, in particular, performance of the transistor 150b may be less pronounced than expected, in particular when the gate length is in the range of 45 nm and significantly less.

In view of the situation described above, the present disclosure relates to manufacturing techniques in which transistor performance is to be increased on the basis of strain-inducing layers formed above transistors, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to techniques in which the stress transfer mechanism of strain-inducing materials formed above transistors may be enhanced by reducing the size of a spacer structure or removing one or more spacer elements, while taking into consideration any negative effects of an etch process that is used for removing material of the sidewall spacer structure. Without intending to restrict the present disclosure to any theory or explanation, it is nevertheless believed that the process of reducing the size of the gate electrode structure prior to forming a strain-inducing dielectric material thereabove may result in the generation of metal-based contaminants, which in turn may have a negative influence on certain transistor characteristics. For example, according to the principles disclosed herein, it is assumed that metal-based contaminants that may be present at the surface area of the gate electrode structure after reducing the size of the sidewall spacer structure may result in an increased parasitic capacitance between the gate electrode structure and contact elements formed so as to connect to the drain and/or source regions of the transistor. This increased parasitic capacitance, which is frequently referred to as fringing capacitance, may result in reduced switching speed of the transistor, which in turn linearly deteriorates the AC signal processing performance. Furthermore, the presence of metal-based contaminants at or in the vicinity of the gate electrode structure may, in certain cases, also contribute to increased leakage currents. Based on the above finding, the present disclosure contemplates process techniques in which metal-based contaminants may be removed, at least to a certain degree, prior to forming one or more strain-inducing materials above and adjacent to the gate electrode structure.

One illustrative method disclosed herein comprises removing material from a sidewall spacer structure of a gate electrode structure of a transistor, wherein the sidewall spacer structure comprises a metal silicide. The metal further comprises performing a wet chemical cleaning process after removing material of the sidewall spacer structure. Additionally, the method comprises forming a strain-inducing layer above the transistor after performing the wet chemical cleaning process.

A further illustrative method disclosed herein comprises forming a metal silicide in drain and source regions and a gate electrode structure of a transistor by using a sidewall spacer structure of the gate electrode structure as a mask. Moreover, the method comprises reducing a size of the sidewall spacer structure by performing a plasma assisted etch process. The method further comprises removing metal-based contaminants from the transistor that comprises the sidewall spacer structure of reduced size. Additionally, the method comprises forming a strain-inducing layer above the transistor.

A still further illustrative method disclosed herein comprises performing a first removal process so as to remove material from a first sidewall spacer structure of a first gate electrode structure of a first transistor and from a second sidewall spacer structure of a second gate electrode structure of a second transistor. The first and second transistors are of different conductivity type. The method further comprises performing a second removal process after the first removal process so as to reduce an amount of metal-based species on surface areas of the first and second transistors. Furthermore, a first strain-inducing layer is formed above the first transistor and a second strain-inducing layer is formed above the second transistor, wherein the first and second strain-inducing layers generate a different type of strain.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of a semiconductor device during various manufacturing stages when applying a dual stress liner approach on the basis of a spacer structure of reduced size, according to conventional strategies;

FIG. 1d schematically illustrates a cross-sectional view of one of the transistors of FIGS. 1a-1c, wherein a mechanism is provided that is assumed to significantly contribute to performance deterioration of the conventional process strategy described with respect to FIGS. 1a-1c;

FIGS. 2a-2c schematically illustrate cross-sectional views of a semiconductor device during various manufacturing stages in providing a strain-inducing material above a gate electrode structure having formed thereon a spacer structure of reduced size, according to illustrative embodiments; and

FIGS. 2d-2e schematically illustrate cross-sectional views of the semiconductor device according to further illustrative embodiments in which different types of strain-inducing materials are provided above transistors of different conductivity type.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

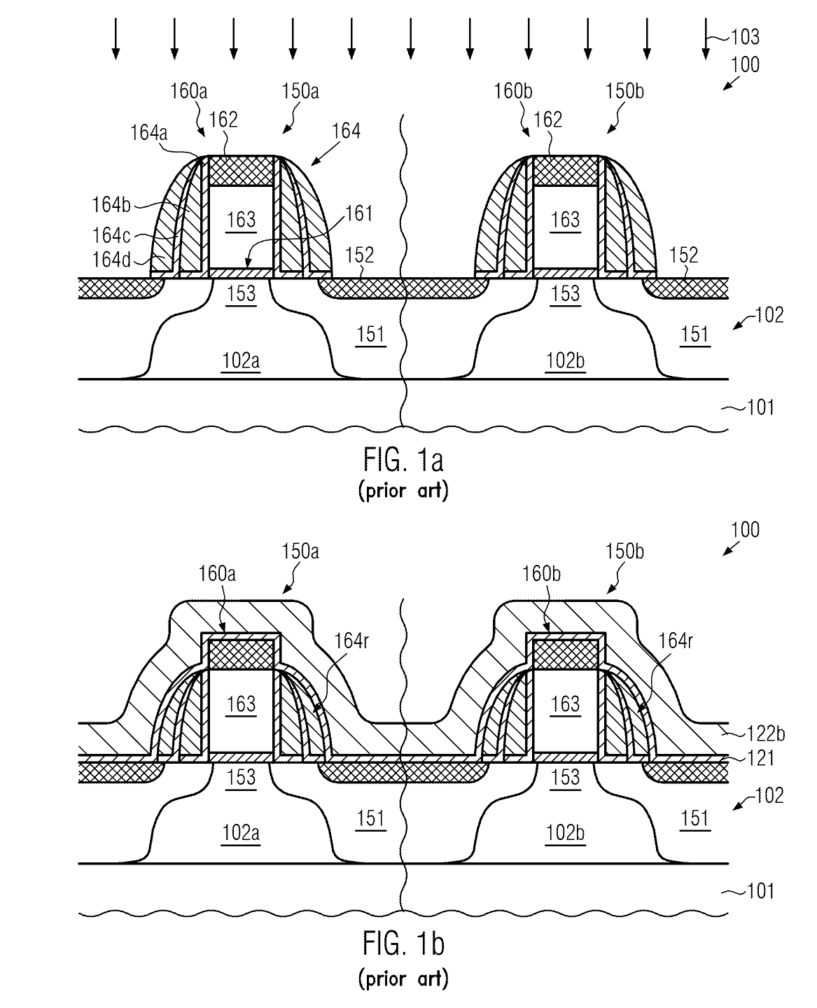

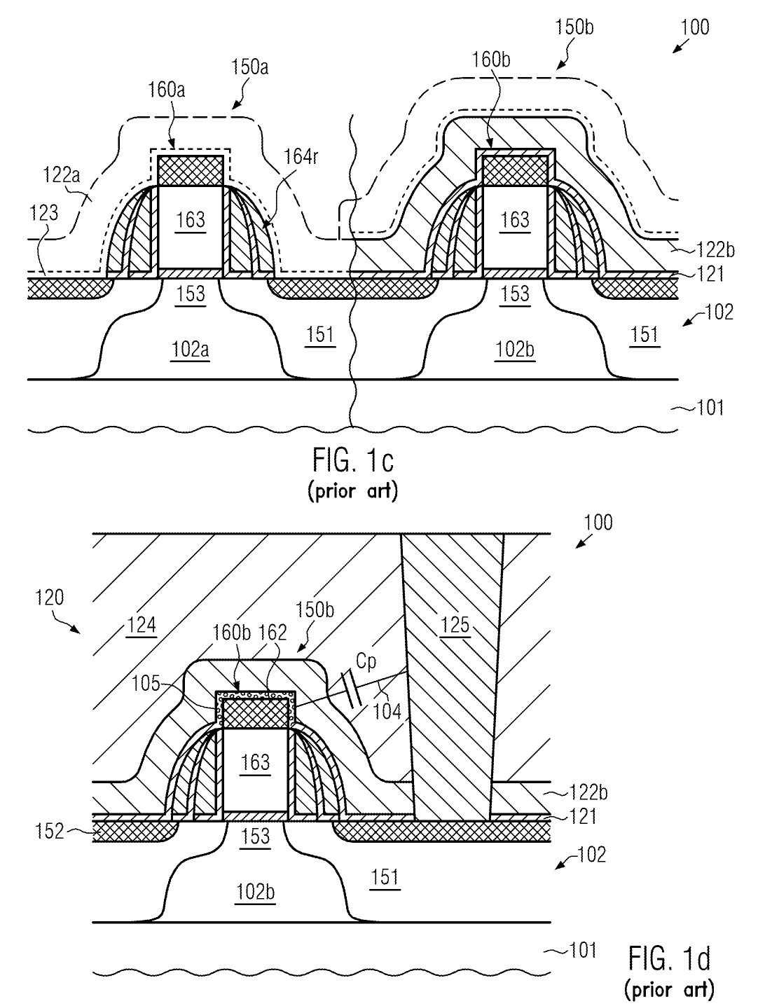

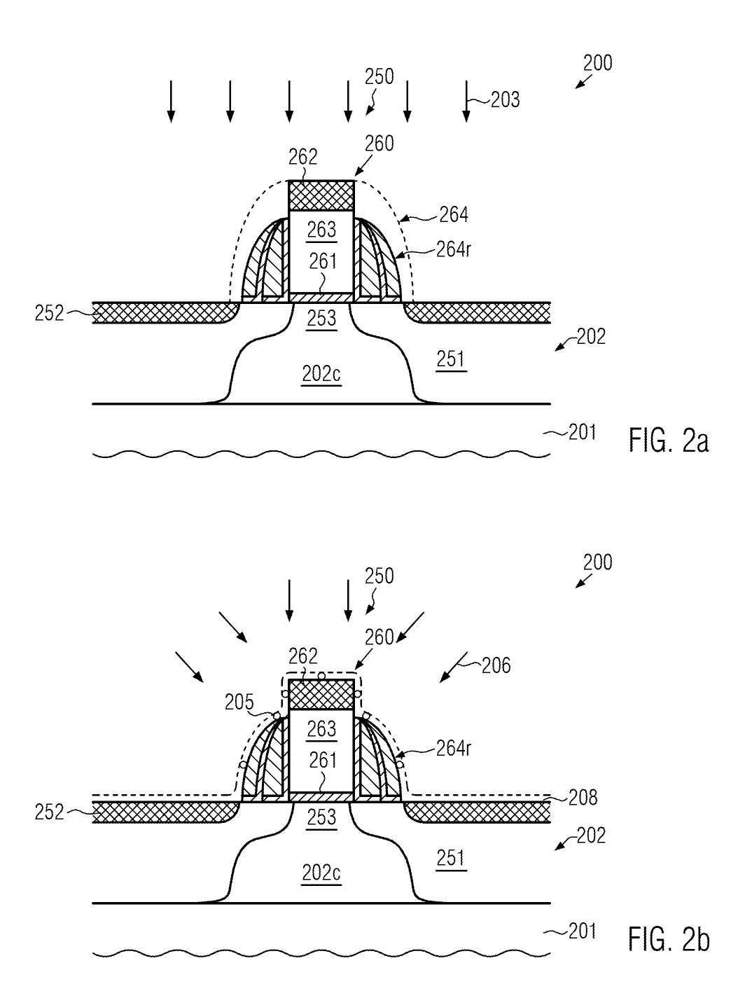

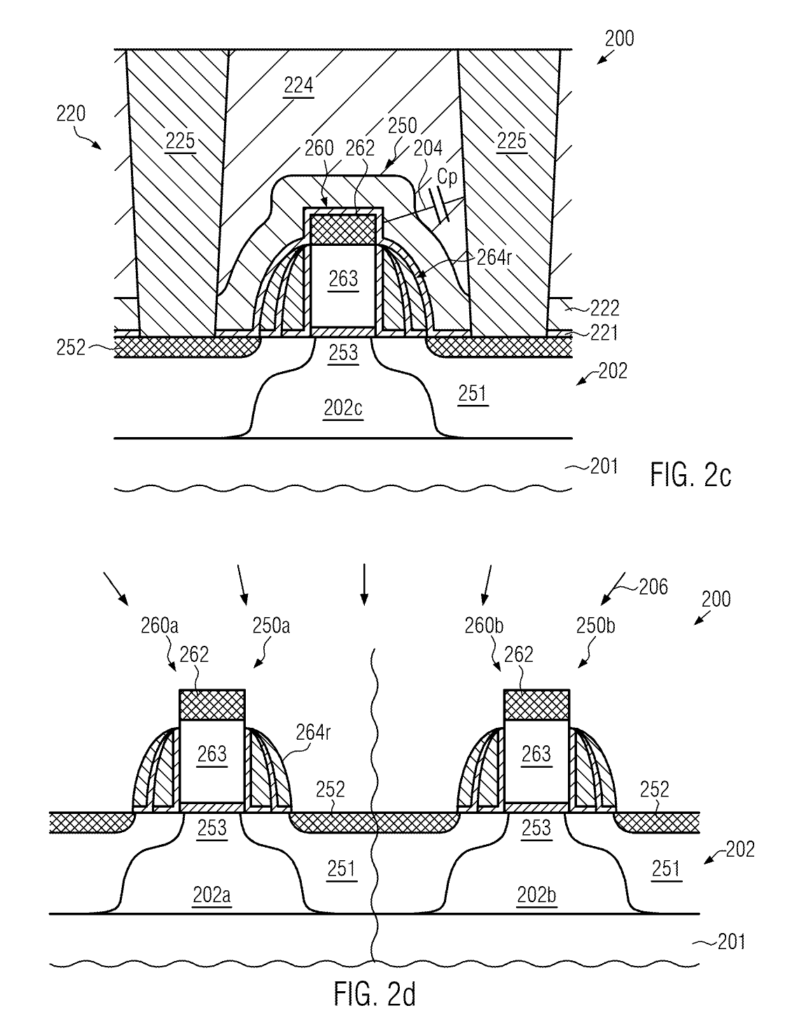

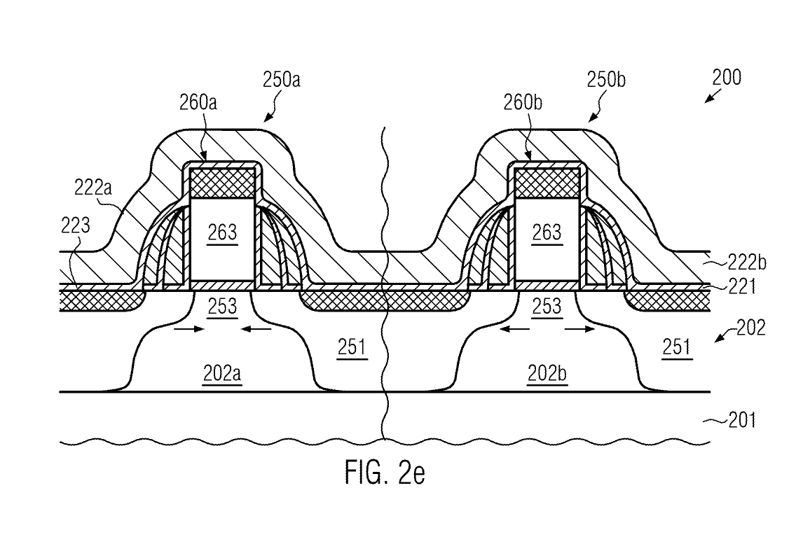

Generally, the present disclosure provides manufacturing techniques in which less pronounced performance increase of a strain-inducing mechanism based on overlying strain-inducing materials may be compensated for by introducing an additional removal process or cleaning process, which is believed to contribute to superior transistor performance, for instance with respect to parasitic capacitance between a gate electrode structure and contact elements. As discussed above, basically, very efficient process strategies are available for providing a strain-inducing material above the transistor, wherein the size reduction of a spacer structure previously used as an efficient mask may contribute to a reduced lateral offset of the strain-inducing material from the channel region of the transistor under consideration. In order to identify any disadvantageous mechanism in the conventional process flow, a detailed analysis has been performed. It is believed, without intending to restrict the present disclosure to any explanation in this respect, that additional metal contaminants may contribute to reduced transistor performance, as will be explained in more detail with reference to FIG. 1 d. Furthermore, further illustrative embodiments will then be described with reference to FIGS. 2a-2e, while also referring to FIGS. 1a-1d, if required.

FIG. 1d schematically illustrates a cross-sectional view of the device 100 wherein, for convenience, the transistor 150b only is illustrated. As discussed above, it has been recognized that, in particular, the transistor 150b may exhibit reduced performance when applying the above-identified process strategy. In accordance with the above-described process flow, the transistor 150b may comprise the strain-inducing layer 122b, possibly in combination with the layer 121, followed by an interlayer dielectric material 124 of a contact level 120 of the device 100. Typically, the interlayer dielectric material 124 may be comprised of silicon dioxide and the like. Furthermore, a contact element 125, for instance comprising tungsten and the like, possibly in combination with one or more appropriate conductive barrier materials (not shown), may be formed so as to connect to the drain or source regions of the transistor 150b, i.e., to the corresponding metal silicide region 152. The contact level 120 may be formed on the basis of any well-established process strategy.

When operating the transistor 150b, the parasitic capacitance 104 between the contact element 125 and the gate electrode structure 160b may have a significant influence, in particular on the AC performance. The capacitance 104 is determined by, among other things, the height of the gate electrode structure 160b, the lateral distance between the gate electrode structure 160b, i.e., the electrode material thereof, and the contact element 125, the dielectric characteristics of the dielectric materials positioned between the electrode material of the gate electrode structure 160b and the contact element 125 and the like. Upon examining the gate electrode structure 160b, metal-based contaminants 105 have been identified, which may form an additional conductive corona around a significant portion of the surface area of the gate electrode structure 160b. Consequently, the electrically effective distance between the gate electrode structure 160b and the contact element 125 may be reduced, thereby increasing the parasitic capacitance 104. Consequently, it is believed that the presence of the metal-based contaminants 105, which may comprise nickel, nickel silicide and the like, may result in a less pronounced gain in performance since the increased parasitic capacitance 104 may partly offset the gain in stress transfer efficiency, which is achieved by reducing the size of the gate electrode structure prior to forming the strain-inducing material 122b. It is believed that metal species may be sputtered off from the regions 152, 162 during the plasma-based etch process 103 (FIG. 1a), since typically a pronounced physical component may be applied during this etch process, as is typical for plasma assisted etch strategies. Hence the corresponding nickel silicide or nickel species may accumulate on surface areas and may be subsequently incorporated into the layer 121 or 122b during the subsequent plasma assisted deposition process.

Since it is extremely difficult to increase etch resistivity of the metal silicide in the regions 152, 162, and since a less pronounced physical and, thus, directional component of the plasma assisted etch process may not be compatible with the removal characteristics, in particular in combination with sensitive gate material, which must not be exposed, the present disclosure contemplates process techniques in which an additional removal process or cleaning process is applied so as to reduce the amount of metal-based contaminants prior to forming a strain-inducing material of the gate electrode structure.

FIG. 2a schematically illustrates a semiconductor device 200 comprising a substrate 201 and a semiconductor layer 202, in and above which may be formed a transistor 250. The transistor 250 may comprise drain and source regions 251 formed in an active region 202c of the semiconductor layer 202. Furthermore, metal silicide regions 252 may be formed in the drain and source regions with a well-defined lateral offset with respect to a channel region 253. Moreover, a gate electrode structure 260 may comprise a gate dielectric layer 261 in combination with an electrode material 263 which may comprise one or more conductive components, followed by a metal silicide material 262. Furthermore, a spacer structure 264 may be provided on sidewalls of the gate electrode structure 260, wherein the size of the structure 264 may be reduced so as to obtain a spacer structure 264r of reduced size.

With respect to the components described so far, it is to be appreciated that these components may have the same features and characteristics as are also discussed above with respect to the semiconductor 100 described in combination with FIGS. 1a-1c. That is, the transistor 250 may represent a P-channel transistor or an N-channel transistor having characteristics similar to the transistors 150a, 150b, as previously discussed. In particular, the gate electrode structure 260 may be provided with a gate length of 50 nm and less and may have incorporated therein a high-k dielectric material in combination with appropriate metal-containing electrode materials, such as titanium nitride and the like, in combination with a silicon and/or germanium based electrode material. It should be understood, therefore, that the gate dielectric layer 261 may comprise a high-k dielectric material, such as a hafnium-based dielectric material, a zirconium-based dielectric material, an aluminum-based dielectric material and the like. Furthermore, two or more different types of high-k dielectric material may be incorporated in the layer 261, if considered appropriate. Similarly, two or more types of metal-containing electrode materials may be incorporated in the material 263.

The semiconductor device 200 as illustrated in FIG. 2a may be formed on the basis of similar process techniques as discussed above with reference to the device 100. For example, after completing the basic transistor configuration, i.e., forming the metal silicide regions 252, 262 after having completed any high temperature processes, a removal process or etch process 203 may be applied, for instance on the basis of a plasma assisted recipe, in order to remove material of the space structure 264 so as to obtain the spacer structure of reduced size 264r. As discussed earlier with reference to the device 100, the etch process 203 may be performed on the basis of well-established plasma assisted etch recipes, for instance for removing silicon nitride material selectively with respect to silicon dioxide and metal silicide. It should be appreciated that the generation of metal-based contaminants during the process 203 may affect the further processing, as discussed above with reference to FIG. 1d.

FIG. 2b schematically illustrates the device 200 according to illustrative embodiments in which a further removal process 206, which may also be referred to as a cleaning process, may be performed on the basis of an appropriate wet chemistry so as to remove or at least significantly reduce the amount of metal-based contaminants 205. These contaminants may have been removed from the regions 252, 262 due to a sputter effect during the plasma based etch process and may lead to a re-deposition on any exposed surface area. For this reason, the removal process 206 may be configured such that the wet chemistry used therein may efficiently attack and remove metal-based species, such as nickel silicide, nickel, platinum and any other metal components. To this end, in some illustrative embodiments, the wet chemical process 206 may be performed on the basis of SPM (sulfuric acid/hydrogen peroxide mixture), SOM (sulfuric acid/ozone mixture), aqua regia and the like. It should be appreciated, however, that any other wet chemical recipes may be applied which are effective in removing the contaminants 205. On the other hand, the process 206 is appropriately controlled, for instance by setting the process time, in order to not unduly remove material of the regions 252, 262. In this respect, it is to be noted that the contaminants 205 may relatively loosely adhere to the surface areas, thereby allowing an efficient removal without unduly consuming the material of the regions 252, 262.

In other illustrative embodiments, a sacrificial layer 208 may be formed prior to the removal process 206, wherein the contaminants 205 may be efficiently “incorporated” into the layer 208, which may be provided in the form of a silicon dioxide material and the like, so that the layer 208, including the contaminants 205, may be efficiently removed during the process 206. In this case, the corresponding wet chemistry may be less aggressive with respect to metal components and may thus provide superior selectivity with respect to the regions 252, 262, while nevertheless enabling an efficient removal of the contaminants 205 together with the sacrificial material 208.

FIG. 2c schematically illustrates the device 200 in a further advanced manufacturing stage. As illustrated a strain-inducing material 222, which may comprise one or more strain-inducing layers (not shown), may be formed above the transistor 250, possibly in combination with an etch stop layer 221, if required. The internal stress level of at least the layer 222 is selected such that a desired type of strain is induced in a channel region 253 of the transistor 250, as is also discussed above. In this case, the reduced size of the spacer structure 264r ensures highly efficient stress transfer efficiency, as is also explained above. Moreover, an interlayer dielectric material 224, such as silicon dioxide and the like, may be provided, thereby forming, in combination with respective contact elements 225, a contact level 220 of the device 200.

Hence, due to the previous reduction of the amount of metal-based contaminants, the materials 221 and 222 may be deposited in a state in which an undue “metal corona,” in particular at the gate electrode structure 260, may be avoided. Thereafter, the contact level 220 may be completed on the basis of any well-established process techniques. Consequently, for given design dimensions of the device 200, the parasitic capacitance 204 may be reduced compared to the conventional case as illustrated in FIG. 1d, since the electrically effective distance between the gate electrode structure 260 and the contact elements 225 may not be unduly increased.

In this respect, measurements have been performed, for instance by using appropriate electrical test circuitry, such as a ring oscillator and the like, which indicates increased ring oscillator frequency when using transistors such as the transistor 250 compared to ring oscillator circuitry formed on the basis of the transistor 150b of FIG. 1d. That is, for otherwise identical transistor characteristics, a significant increase of a seed performance may be achieved, thereby indicating that the concept of reducing the size of a spacer structure for enhancing stress transfer efficiency may be exploited more fully by applying the removal process 206 of FIG. 2b.

FIG. 2d schematically illustrates a cross-sectional view of the semiconductor device 200 according to illustrative embodiments in which a first transistor 250b may be formed in and above a first active region 202b and a second transistor 250a may be formed in and above a second active region 202a. The transistors 250a, 250b may be of different conductivity type and may thus require a different type of strain to be induced in the active regions 202a, 202b, respectively. In the manufacturing stage shown, the transistor 250a may comprise a gate electrode structure 260a and the transistor 250b may comprise a gate electrode structure 260b, wherein generally the transistors 250a, 250b may have a similar configuration as the transistor 250 previously described with reference to FIGS. 2a-2c, or the transistors 250a, 250b may have similar characteristics as the transistors of the device 100, as described above with reference to FIGS. 1a-1c. Moreover, the gate electrode structures 260a, 260b may comprise the spacer structure 264r of reduced size, which may be obtained by applying the etch process 203 of FIG. 2a commonly to the transistors 250a, 250b. Thereafter the wet chemical process 206 may be commonly applied to the transistors 250a, 250b in order to remove or at least reduce the amount of metal-based species or contaminants, as discussed above. Thereafter, the further processing may be continued by providing one or more material layers of high internal stress level, as is required for implementing a respective strain-inducing mechanism for the transistors 250a, 250b.

FIG. 2e schematically illustrates the semiconductor device 200 according to illustrative embodiments in which a strain-inducing material 222b may be formed above the transistor 250b so as to induce a desired type of strain in the channel region 253, such as a tensile strain, when a N-channel transistor is considered. Similarly, a strain-inducing material 222a may be formed above the transistor 250a in order to induce a desired type of strain in the channel region 253, such as a compressive strain, if a P-channel transistor is considered. Moreover, respective etch stop layers 221 and 223 may be provided, if required, in combination with the materials 222b, 222a, respectively.

The device 200 as shown in FIG. 2e may be formed on the basis of a dual stress liner approach, as previously discussed with reference to the device 100 when describing the conventional process strategy in the context of FIGS. 1a-1c. In other illustrative embodiments (not shown), any other appropriate process strategy may be applied, for instance forming a strain-inducing layer above the transistors 250a, 250b, relaxing the internal stress level above one of the transistors and providing one or more layers of a different internal stress level. Furthermore, it should be appreciated that silicon nitride may be used as an efficient strain-inducing material for the layers 222a, 222b, while in other cases other appropriate materials, for instance metal-containing materials, may be provided which may be deposited on the basis of very high internal stress levels. In this case, any appropriate intermediate layers may have to be provided so as to ensure electrical integrity of the transistors 250a, 250b. Moreover, when applying a dual stress liner approach, i.e., when depositing a first material of a first internal stress level, patterning the first material, depositing a second layer with a second internal stress level and patterning the second layer, the different materials of different internal stress levels may be applied in any order, for instance a tensile stressed material may be deposited first, followed by the compressively stressed dielectric material after patterning the previously deposited material, while in other cases the compressively stressed material may be deposited first.

As a result, the present disclosure provides manufacturing techniques in which superior stress transfer efficiency may be achieved by using a spacer structure of reduced size, wherein negative effects of the corresponding material removal process may be compensated for or may at least be reduced by incorporating an additional wet chemical removal or cleaning process. Consequently, superior AC performance of transistors may be achieved since, for instance, a reduction of the parasitic fringing capacitance may result in increased switching speed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
removing material from a sidewall spacer structure of a gate electrode structure of a transistor, said sidewall spacer structure comprising a metal silicide;
performing a wet chemical cleaning process after removing material of said sidewall spacer structure; and
forming a strain-inducing layer above said transistor after performing said wet chemical cleaning process.

2. The method of claim 1, wherein removing material from said sidewall spacer structure comprises performing a plasma assisted etch process.

3. The method of claim 1, wherein performing a wet chemical cleaning process comprises applying a metal removing agent.

4. The method of claim 3, wherein said metal removing agent comprises at least one of sulfuric acid, hydrogen peroxide, ozone and aqua regia.

5. The method of claim 1, further comprising removing material of a second sidewall spacer structure of a second transistor and performing said wet chemical cleaning process in the presence of said second sidewall spacer structure after removal of material thereof, wherein said transistor and said second transistor are of different conductivity type.

6. The method of claim 5, further comprising forming a second strain-inducing layer above said second transistor, wherein said strain-inducing layer and said second strain-inducing layer induce a different type of strain.

7. The method of claim 5, further comprising, prior to forming said second strain-inducing layer, forming said strain-inducing layer above said transistor and said second transistor and removing said strain-inducing layer from above said second transistor.

8. The method of claim 1, further comprising forming said metal silicide in said gate electrode structure and in drain and source regions of said transistor by using said sidewall spacer structure as a mask prior to removing material thereof.

9. The method of claim 1, wherein said gate electrode structure comprises a gate insulation layer including a high-k dielectric material.

10. The method of claim 1, wherein a length of said gate electrode structure is 50 nm or less.

11. A method, comprising:
forming a metal silicide in drain and source regions and a gate electrode structure of a transistor by using a sidewall spacer structure of said gate electrode structure as a mask;
reducing a size of said sidewall spacer structure by performing a plasma assisted etch process;
removing metal-based contaminants from said transistor comprising said sidewall spacer structure of reduced size; and
forming a strain-inducing layer above said transistor.

12. The method of claim 11, wherein removing metal-based contaminants comprises performing a wet chemical cleaning process.

13. The method of claim 12, wherein said wet chemical cleaning process is performed by using at least one of sulfuric acid/hydrogen peroxide mixture, a sulfuric acid/ozone mixture and aqua regia.

14. The method of claim 11, further comprising forming said gate electrode structure by using a high-k dielectric material.

15. The method of claim 11, further comprising forming a metal silicide in second drain and source regions and a second gate electrode structure of a second transistor and reducing a size of a second sidewall spacer structure of said second gate electrode structure of said second transistor, wherein said transistor and said second transistor are of different conductivity type.

16. The method of claim 15, wherein the sizes of said first and second sidewall spacer structures are commonly reduced in said plasma assisted etch process.

17. The method of claim 15, further comprising forming a second strain-inducing layer selectively above said second transistor, wherein said strain-inducing layer and said second strain-inducing layer induce a different type of strain.

18. The method of claim 17, further comprising forming said strain-inducing layer above said transistor and said second transistor and removing said strain-inducing layer selectively from above said second transistor prior to forming said second strain-inducing layer.

19. A method, comprising:
performing a first removal process so as to remove material from a first sidewall spacer structure of a first gate electrode structure of a first transistor and a second sidewall spacer structure of a second gate electrode structure of a second transistor, said first and second transistors being of different conductivity type;
performing a second removal process after said first removal process so as to reduce an amount of metal-based species on surface areas of said first and second transistors;
forming a first strain-inducing layer above said first transistor; and
forming a second strain-inducing layer above said second transistor, said first and second strain-inducing layers generating a different type of strain.

20. The method of claim 19, wherein performing said first and second removal processes comprises performing a plasma assisted etch process as said first removal process and performing a wet chemical cleaning process as said second removal process.
